(19) United States
(12) Patent Application Publication
(10) Pub. No.: US 2016/0005965 A1
(43) Pub. Date: Jan. 7, 2016

(54) MEMORY CELLS HAVING A FIRST SELECTING CHALCOGENIDE MATERIAL AND A SECOND SELECTING CHALCOGENIDE MATERIAL AND METHODS THEROF

(71) Applicant: Micron Technology, Inc., Boise, ID (US)

(72) Inventor: Andrea Redaelli, Casatenovo (IT)

(21) Appl. No.: 14/321,222

(22) Filed: Jul. 1, 2014

(51) Int. Cl. H01L 45/00; H01L 27/24

(52) U.S. Cl. CPC H01L 45/141; H01L 45/06; H01L 45/1233; H01L 45/1253; H01L 45/1608; H01L 27/2463

(57) ABSTRACT

The present disclosure includes memory cells and methods of forming the same. The memory cells disclosed herein can include a first selecting chalcogenide material, a second selecting chalcogenide material, and a storage material.

### TECHNICAL FIELD

The present disclosure relates generally to memory cells, and more particularly to memory cells having first selecting chalcogenide material and a second selecting chalcogenide material, memory arrays, and methods of forming the same.

### BACKGROUND

Memory devices are utilized as non-volatile memory for a wide range of electronic applications in need of high memory densities, high reliability, and data retention without power. Non-volatile memory may be used in, for example, personal computers, portable memory sticks, solid state drives (SSDs), digital cameras, cellular telephones, portable music players such as MP3 players, movie players, and other electronic devices.

Memory devices are typically provided as internal, semiconductor, integrated circuits in computers or other electronic devices. There are many different types of memory, including random-access memory (RAM), read only memory (ROM), dynamic random access memory (DRAM), synchronous dynamic random access memory (SDRAM), flash memory, and resistance variable memory, among others. Types of resistance variable memory include phase change random access memory (PCRAM) and resistive random access memory (RRAM), for instance.

Resistance variable memory devices can include a resistance variable material, e.g., a phase change material, for instance, which can be programmed into different resistance states to store data. The particular data stored in a resistance variable material cell can be read by sensing the cell's resistance e.g., by sensing current and/or voltage variations based on the resistance of the resistance variable material.

### BRIEF DESCRIPTION OF THE DRAWINGS

FIG. 1 illustrates a portion of a memory cell in accordance with a number of embodiments of the present disclosure.

FIG. 2 illustrates a portion of a resistive memory array in accordance with a number of embodiments of the present disclosure.

FIG. 3 illustrates a portion of a three dimensional resistive memory array in accordance with a number of embodiments of the present disclosure.

### DETAILED DESCRIPTION

Memory cells having a first selecting chalcogenide material and a second selecting chalcogenide material and methods of manufacturing the same are described herein. As an example, a memory cell can include a first selecting chalcogenide material, a second selecting chalcogenide material, and a storage material formed between the first selecting chalcogenide material the second selecting chalcogenide material. In some embodiments the storage material can comprise a storage chalcogenide material. In some other embodiments the storage material can comprise a storage conductive-bridging material or a storage resistive material, for example.

Previous memory cells have utilized only a single selecting chalcogenide material. The single selecting chalcogenide material can be operated, e.g., turned on/off, to select/deselect a memory cell in order to perform operations such as data programming, e.g., writing, and/or data sensing, e.g., reading operations.

Embodiments of the present disclosure can provide benefits such as improved thermal isolation, utilization of lower programming currents, reduced disturb, improved symmetry of cell electrical characteristics, and/or reduced ion migration, among others, as compared to previous memory cells having only a single selecting chalcogenide element. As mentioned, memory cells disclosed herein can include a first selecting chalcogenide material and a second selecting chalcogenide material. Embodiments of the present disclosure can provide that the first selecting chalcogenide material and the second selecting chalcogenide material are separated by a storage material, e.g., the storage material can be formed between the first selecting chalcogenide material and the second selecting chalcogenide material.

Because the storage materials of memory cells according to the present disclosure are formed between the first selecting chalcogenide material and the second selecting chalcogenide material, memory cells according to the present disclosure can provide improved thermal isolation as compared to previous memory cells having only a single selecting chalcogenide material. For instance, there may be greater thermal resistances, e.g., greater thermal isolation, associated with a location having a temperature hot spot for a phase change of the storage material according to the present disclosure, as compared to other memory cells. For example, the location having a temperature hot spot, e.g., within the storage material, may be more thermally isolated from conducive lines, such as access lines and data/sense lines, which are discussed further herein. The improved thermal isolation of the memory cells disclosed herein can provide that lower energy, e.g., lower programming currents, may be utilized for programming memory cells according to the present disclosure, as compared to previous memory cells. Also, the lower programming energy can help reduce programming disturb, e.g., energy inadvertently provided to neighboring memory cells. Further advantageously, the lower programming currents may help reduce ion migration, e.g., ion diffusion within the storage material while in a molten phase. Ion migration reduction is desirable because ion migration can result in faulty memory cell operations.

In the detailed description of the present disclosure, reference is made to the accompanying drawings that form a part hereof, and in which is shown by way of illustration how a number of embodiments of the disclosure may be practiced. These embodiments are described in sufficient detail to enable those of ordinary skill in the art to practice the embodiments of this disclosure, and it is to be understood that other embodiments may be utilized and that process, electrical, and/or structural changes may be made without departing from the scope of the present disclosure.

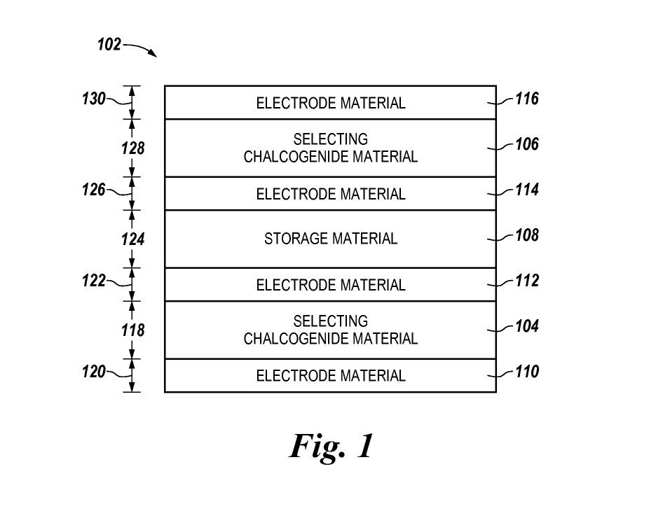

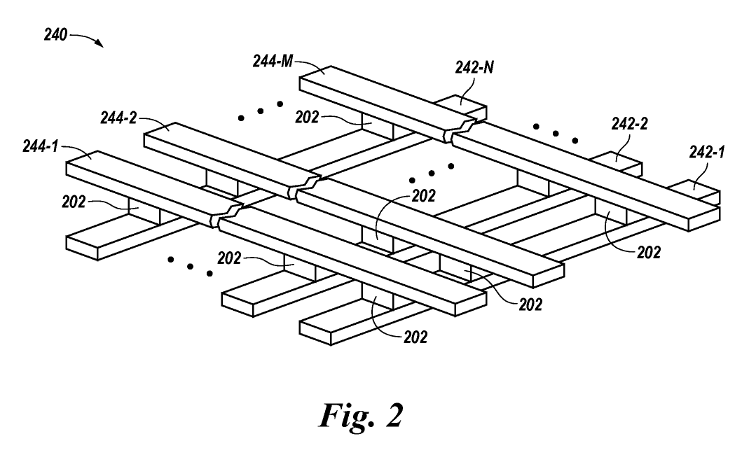

The figures herein follow a numbering convention in which the first digit or digits correspond to the drawing figure number and the remaining digits identify an element or component in the drawing. Similar elements or components between different figures may be identified by the use of similar digits. For example, 102 may reference element “2” in FIG. 1, and a similar element may be referenced as 202 in FIG. 2. Also, as used herein, “a number of” a particular element and/or feature can refer to one or more of such elements and/or features.

FIG. 1 illustrates a portion of a memory cell 102 in accordance with a number of embodiments of the present disclosure. As illustrated in FIG. 1, the memory cell 102 can include: a selecting chalcogenide material 104, e.g., a first selecting chalcogenide material; a selecting chalcogenide material 106, e.g., a second selecting chalcogenide material; a storage material 108; an electrode material 110; an electrode material 112; an electrode material 114; and an electrode material 116. The selecting chalcogenide materials 104, 106 can be operated, e.g., turned on/off, to select/deselect a memory cell in order to perform operations such as data programming, e.g., writing, and/or data sensing, e.g., reading operations. For instance, responsive to an applied voltage across the memory cell 102 that is less than a threshold voltage, the selecting chalcogenide materials 104, 106 can remain in an “off” state, e.g., an electrically nonconductive state. Alternatively, responsive to an applied voltage across the memory cell 102 that is greater than the threshold voltage, the selecting chalcogenide materials 104, 106 can be in an “on” state. The storage material 108 can store a data state of the memory cell 102.

As illustrated in FIG. 1, the selecting chalcogenide material 104 can be formed on, e.g., subsequent to, an electrode material 110. In the example illustrated in FIG. 1, the selecting chalcogenide material 104 is formed on, e.g., in contact with, the electrode material 110. However, examples of the present disclosure are not so limited. For instance, a number of intervening materials, not shown in FIG. 1, may separate a material formed on another material, such as the selecting chalcogenide material 104 and the electrode material 110, among others.

Embodiments of the present disclosure provide that the selecting chalcogenide material 104 does not store a data state of the memory cell 102, e.g., in contrast to the storage material 108, the selecting chalcogenide material 104 does not have different resistance values that are stable over time. For instance, the selecting chalcogenide material 104 can be in a perpetual amorphous state. The selecting chalcogenide material 104 can include As, Te, Ge, Si, S, and/or Se. Some specific examples of the selecting chalcogenide material 104 include AsTeGeSi, As₂Te₃Ge, and As₂Se₃Ge.

The selecting chalcogenide material 104 can have a thickness 118 in a range from 6 nanometers (nm) to 20 nm. Some embodiments of the present disclosure provide that the selecting chalcogenide material 104 can have a thickness 118 in a range from 7.5 nm to 15 nm.

As mentioned, the selecting chalcogenide material 104 can be formed on the electrode material 110. The electrode material 110 can include materials such as Ti, Ta, W, Al, Cr, Zr, Nb, Mo, Hf, B, C, N, conductive nitrides of the aforementioned materials, e.g., TiN, TaN, WN, CN, etc., and/or combinations thereof. The electrode material 110 can have a thickness 120 in a range from 8 nm to 15 nm.

As illustrated in FIG. 1, the electrode material 112 can be formed on the selecting chalcogenide material 104. The electrode material 112 can be similar to the electrode material 110, e.g., the electrode material 112 can include a number of materials as discussed with the electrode material 110. Additionally, the electrode material 112 can have a thickness 122 in a range from 8 nm to 20 nm.

Embodiments of the present disclosure provide that the memory cell 102 includes the storage material 108. As illustrated in FIG. 1, the storage material 108 can be formed on the electrode material 112. Embodiments of the present disclosure provide that the storage material 108 is programmable, e.g. the storage material 108 may have a variable resistance.

Embodiments of the present disclosure provide that the storage material 108 can be a resistance variable material that can be programmed into different resistance states to store data. The storage material 108 can include, for example, one or more resistance variable materials such as a metal oxide material, such as alkaline metal oxides, e.g., Li₂O, Na₂O, K₂O, Rb₂O, Cs₂O, BeO, MgO, CaO, SrO, and BaO, refractive metal oxides, e.g., NbO, NbO₂, Nb₂O₅, MoO₂, MoO₃, Ta₂O₅, W₂O₃, WO₂, WO₃, ReO₂, ReO₃, and Re₂O₇, and binary metal oxides, e.g., CuₓO_{y}, WOₓ, Nb₂O₅, Al₂O₃, Ta₂O₅, TiOₓ, ZrOₓ, NiₓO, and FeₓO, among others. Other examples of resistance variable materials associated with the storage material 108 of the memory cell 102 can include chalcogenides, binary metal oxides, colossal magnetoresistive materials such as Pr₍ᵢ₋ₓ₎CaNMnO₃ (PCMO), La₍₁₋ₓ₎CaxMnO₃ (LCMO), and Ba₍ᵢ₋ₓ₎SrₓTiO₃, among others, and/or perovskite oxides such as doped or undoped SrTiO₃, SrZrO₃, and BaTiO₃, and polymer materials such as Bengala Rose, AlQ₃Ag, Cu-TCNQ, DDQ, TAPA, and Fluorescine-based polymers, among others. As such, the memory cell 102 can be a RRAM cell, a PCRAM cell, and/or a conductive bridging memory cell, among various other types of resistive memory cells. The storage material 108 can include materials such as In, Ge, Sb, Te, Si, O, N, and/or combinations thereof. Some specific examples, e.g., chalcogenides, of the storage material 108 include Ge₂Sb₂Te₅, Ge₁Sb₂Te₄, Ge₁Sb₄Te₇, Ge—Te, In—Se, Sb—Te, Ga—Sb, In—Sb, As—Te, Al—Te, Ge—Sb—Te, Te—Ge—As, In—Sb—Te, Te—Sn—Se, Ge—Se—Ga, Bi—Se—Sb, Ga—Se—Te, Sn—Sb—Te, In—Sb—Ge, Te—Ge—Sb—S, Te—Ge—Sn—O, Te—Ge—Sn—Au, Pd—Te—Ge—Sn, In—Se—Ti—Co, Ge—Sb—Te—Pd, Ge—Sb—Te—Co, Sb—Te—Bi—Se, Ag—In—Sb—Te, Ge—Sb—Se—Te, Ge—Sn—Sb—Te, Ge—Te—Sn—Ni, Ge—Te—Sn—Pd, and Ge—Te—Sn—Pt. Embodiments of the present disclosure are not limited to a particular type of RRAM material.

The storage material 108 can have a thickness 124 in a range from 10 nanometers (nm) to 50 nm. Some embodiments of the present disclosure provide that the storage material 108 can have a thickness 124 in a range from 15 nm to 35 nm.

As illustrated in FIG. 1, an electrode material 114 can be formed on the storage material 108. The electrode material 114 can be similar to the electrode material 110, e.g., the electrode material 114 can include a number of materials as discussed with the electrode material 110. Additionally, the electrode material 114 can have a thickness 126 in a range from 8 nm to 20 nm.

As illustrated in FIG. 1, the selecting chalcogenide material 106 can be formed on the electrode material 114. Embodiments of the present disclosure provide that the selecting chalcogenide material 106 does not store a data state of the memory cell 102, e.g., in contrast to the storage material 108, the selecting chalcogenide material 106 does not have different resistance values that are stable over time. For instance, the selecting chalcogenide material 106 can be in a perpetual amorphous state. The selecting chalcogenide material 106 can be similar to the selecting chalcogenide material 104, e.g., the selecting chalcogenide material 106 can include a number of materials as discussed with selecting chalcogenide material 104.

As illustrated in FIG. 1, the selecting chalcogenide material 104 and the selecting chalcogenide material 106 are in series, e.g., the selecting chalcogenide material 104 and the selecting chalcogenide material 106 are electrically coupled in series, in contrast to be electrically coupled in parallel.

The selecting chalcogenide material 106 can have a thickness 128 in a range from 6 nm to 20 nm. Some embodiments of the present disclosure provide that the selecting chalcogenide material 106 can have a thickness 128 in a range from 7.5 nm to 15 nm.

As illustrated in FIG. 1, the electrode material 116 can be formed on the selecting chalcogenide material 106. The electrode material 116 can be similar to the electrode material 110, e.g., the electrode material 116 can include a number of materials as discussed with the electrode material 110. Additionally, the electrode material 116 can have a thickness 130 in a range from 8 nm to 15 nm.

Some embodiments of the present disclosure provide that the memory cell 102 is symmetric about the storage material 108. For instance, the memory cell 102 can include the electrode material 112, the selecting chalcogenide material 104, and the electrode material 110 and, transverse the storage material 108, the memory cell 102 can include the electrode material 114, the selecting chalcogenide material 106, and the electrode material 116. Being symmetric about the storage material 108, the thickness 122 of the electrode material 112 is equal to the thickness 126 of the electrode material 114, the thickness 118 of the selecting chalcogenide material 104 is equal to the thickness 128 of the selecting chalcogenide material 106, and the thickness 120 of the electrode material 110 is equal to the thickness 130 of the electrode material 116.

Additionally, being symmetric about the storage material 108, the same material or materials can be used to form both the electrode material 112 and the electrode material 114, the same material or materials can be used to form both the selecting chalcogenide material 104 and the selecting chalcogenide material 106, and the same material or materials can be used to form both the electrode material 110 and the electrode material 116. For example, some embodiments of the present disclosure provide that the selecting chalcogenide material 104 comprises a first material and the selecting chalcogenide material 106 comprises a second material that is a same material as the first material.

The memory cell 102 being symmetric about the storage material 108 can provide the memory cell 102 has a symmetric thermal profile. For instance, the symmetry can provide that a temperature hot spot for a phase change of the storage material 108 is substantially equally thermally isolated from an access line and a data/sense line, which are discussed further herein.

Some embodiments of the present disclosure provide that the memory cell 102 is asymmetric about the storage material 108. For instance, the memory cell 102 can include the electrode material 112, the selecting chalcogenide material 104, and the electrode material 110 and, transverse the storage material 108, the memory cell 102 can include the electrode material 114, the selecting chalcogenide material 106, and the electrode material 116. Being asymmetric about the storage material 108, the thickness 122 of the electrode material 112 can be different than, e.g., greater or less than, the thickness 126 of the electrode material 114, the thickness 118 of the selecting chalcogenide material 104 can be different than the thickness 128 of the selecting chalcogenide material 106, and/or the thickness 120 of the electrode material 110 can be different than the thickness 130 of the electrode material 116.

Additionally, being asymmetric about the storage material 108, a different material or materials can be used to form the electrode material 112 and the electrode material 114, a different material or materials can be used to form the selecting chalcogenide material 104 and the selecting chalcogenide material 106, and/or a different material or materials can be used to form the electrode material 110 and the electrode material 116. For example, some embodiments of the present disclosure provide that the selecting chalcogenide material 104 comprises a first material and the selecting chalcogenide material 106 comprises a second material that is a different material as the first material.

The memory cell 102 can be formed using various processing techniques such as atomic material deposition (AMD), e.g., atomic layer deposition (ALD), physical vapor deposition (PVD), chemical vapor deposition (CVD), supercritical fluid deposition (SFD), patterning, etching, filling, chemical mechanical planarization (CMP), combinations thereof, and/or other suitable processes. In accordance with a number of embodiments of the present disclosure, materials may be grown in situ.

FIG. 2 illustrates a portion of a memory array 240 in accordance with a number of embodiments of the present disclosure. The array 240 can be a cross-point array, which may also be referred to as a crossbar array.

The array 240 can include a number memory cells 202, where each memory cell 202 is located at a respective intersection of a first plurality of conductive lines, e.g., access lines, 242-1, 242-2, . . . , 242-N, which may be referred to herein as word lines, and a second plurality of conductive lines, e.g., data/sense lines, 244-1, 244-2, . . . , 244-M, which may be referred to herein as bit lines. The designators N and M can have various values. Embodiments are not limited to a particular number of word lines and/or bit lines. As illustrated, the access lines 242-1, 242-2, . . . , 242-N are substantially parallel to each other and are substantially orthogonal to the data/sense lines 244-1, 244-2, . . . , 244-M, which are substantially parallel to each other; however, embodiments are not so limited. As illustrated in FIG. 2, the array 240 can be a two dimensional array. For example, the memory cells 202 of the array 240 can be arranged between the access lines, 242-1, 242-2, . . . , 242-N and the data/sense lines, 244-1, 244-2, . . . , 244-M in a single tier.

As used herein, the term “substantially” intends that the modified characteristic needs not be absolute, but is close enough so as to achieve the advantages of the characteristic. For example, “substantially parallel” is not limited to absolute parallelism, and can include orientations that are at least closer to a parallel orientation than a perpendicular orientation. Similarly, “substantially orthogonal” is not limited to absolute orthogonalism, and can include orientations that are at least closer to a perpendicular orientation than a parallel orientation. The conductive lines can include conductive material, e.g., a metal material. Examples of the conductive material include, but are not limited to, tungsten, copper, titanium, aluminum, and/or combinations thereof, among other conductive materials.

In operation, a selected memory cell 102 can be programmed by applying a voltage, e.g., a write voltage, across the selected memory cell 102 via a selected access line 242-1, 242-2, . . . , 242-N and a selected data/sense line 244-1, 244-2, . . . , 244-M. The width and/or magnitude of voltage pulses across the selected memory cell 102 can be adjusted, e.g., varied, in order to program the selected memory cell 102 to particular data states, e.g., by adjusting a resistance level of the storage material 108, e.g., by a phase change to the storage material 108. A sensing, e.g., read, operation can be used to determine the data state of a memory cell 102 by a sensing current, for example, on a data/sense line 244-1, 244-2, . . . , 244-M corresponding to the memory cell 102 responsive to a particular voltage applied to a selected access line to which the memory cell 102 is coupled. Sensing operations can also include biasing unselected access lines 242-1, 242-2, . . . , 242-N and/or unselected data/sense lines 244-1, 244-2, . . . , 244-M at particular voltages in order to sense the data state of the selected memory cell 102.

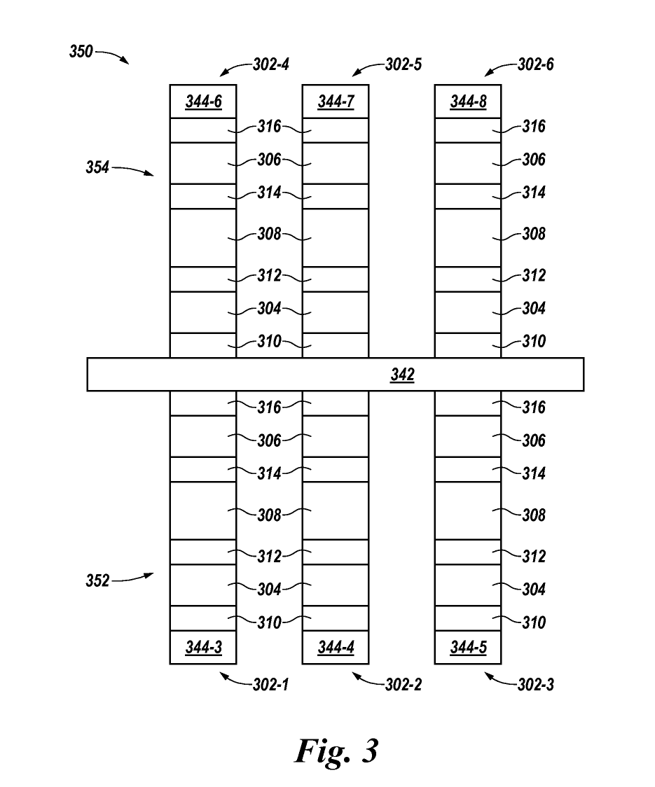

FIG. 3 illustrates a portion of a three dimensional memory array 350 in accordance with a number of embodiments of the present disclosure. As illustrated in FIG. 3, the array 350 includes a plurality memory cells 302-1, 302-2, 302-3, 302-4, 302-5, 302-6 arranged into multiple tiers, e.g., tier 352 and tier 354, which may also be referred to as levels. While FIG. 3 illustrates two tiers, embodiments of the present disclosure are not so limited; the array 350 can include varying numbers of tiers for different applications. In one or more embodiments, the processes of forming a memory cell and/or memory cell array can be repeated a number of times to create a number of tiers.

Each tier, e.g., tiers 352, 354, of the array 350 the memory cells 302 can be arranged in a cross point architecture where the memory cells 302 of adjacent tiers share a plurality of conductive lines, e.g., access lines or data/sense lines. For example, as illustrated in FIG. 3, the memory cells 302-1, 302-2, 302-3 of tier 352 share the access line 342 with the memory cells of 302-4, 302-5, 302-6 of tier 354. Similarly, other cells of tier 352 would share other access lines with other cells of tier 354. Embodiments of the present disclosure are not limited to memory cells 302 of adjacent tiers sharing a plurality of access lines. For instance, some embodiments of the present disclosure provide that memory cells 302 of adjacent tiers share a plurality of data/sense lines. As mentioned, some embodiments of the present disclosure provide that the cells, e.g., cells 302-1, 302-2, 302-3 of tier 352 and cells of 302-4, 302-5, 302-6 of tier 354 can be symmetric. This cell symmetry can provide that cells of adjacent tiers, e.g., tiers 352 and 354, have similar properties, e.g., the cells are indistinguishable from one another. Advantageously, this cell symmetry can provide improved multiple tier arrays, as compared to previous cells.

While the memory cells 302-1, 302-2, 302-3 of tier 352 share the access line 342 with the memory cells of 302-4, 302-5, 302-6 of tier 354, each of the memory cells 302-1, 302-2, 302-3, 302-4, 302-5, 302-6 is associated with a respective data/sense line 344. As shown in FIG. 3, memory cells 302-1, 302-2, 302-3, 302-4, 302-5, 302-6 are respectively associated with data/sense lines 344-3, 344-4, 344-5, 344-6, 344-7, 344-8.

As discussed, some examples of the present disclosure provide that the cells, e.g. cells 302-1, 302-2, 302-3, 302-4, 302-5, 302-6, are symmetric about respective storage materials. Also, as discussed, some examples of the present disclosure provide that the cells, e.g. cells 302-1, 302-2, 302-3, 302-4, 302-5, 302-6, are asymmetric about respective storage materials.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

1. A memory cell, comprising:
a first selecting chalcogenide material;
a second selecting chalcogenide material; and
a storage material formed between the first selecting chalcogenide material the second selecting chalcogenide material.

2. The memory cell of claim 1, further comprising a first electrode material, wherein the first selecting chalcogenide material is formed on a first electrode material.

3. The memory cell of claim 2, further comprising a second electrode material formed between the first selecting chalcogenide material and the storage material.

4. The memory cell of claim 3, further comprising a third electrode material formed between the second selecting chalcogenide material and the storage material.

5. The memory cell of claim 4, further comprising a fourth electrode material, wherein the fourth electrode material is formed on the second selecting chalcogenide material.

6. The memory cell of claim 1, wherein the first selecting chalcogenide material has a thickness that is equal to a thickness of the second selecting chalcogenide material.

7. The memory cell of claim 1, wherein the first selecting chalcogenide material has a thickness that is greater than a thickness of the second selecting chalcogenide material.

8. The memory cell of claim 1, wherein the first selecting chalcogenide material has a thickness that is less than a thickness of the second selecting chalcogenide material.

9. The memory cell of claim 1, wherein the storage material comprises a storage chalcogenide material.

10. The memory cell of claim 1, wherein the first selecting chalcogenide material comprises a first material and the second selecting chalcogenide material comprises a second material that is a same material as the first material.

11. The memory cell of claim 1, wherein the first selecting chalcogenide material comprises a first material and the second selecting chalcogenide material comprises a second material that is a different material as the first material.

12. A memory cell, comprising:
a first selecting chalcogenide material;
a storage material; and
a second selecting chalcogenide material; wherein the first selecting chalcogenide material, the storage material, and the second selecting chalcogenide material are in series.

13. The memory cell of claim 12, wherein the storage material comprises a storage chalcogenide material.

14. The memory cell of claim 13, wherein the storage material comprises a resistance variable material.

15. The memory cell of claim 12, wherein the memory cell is symmetric about the storage material.

16. The memory cell of claim 12, wherein the memory cell is asymmetric about the storage material.

17. The memory cell of claim 12, further comprising a plurality of electrode materials, wherein one of the plurality of electrode materials is formed between the first selecting chalcogenide material and the storage material.

18. The memory cell of claim 17, wherein another of the plurality of electrode materials is formed between the storage material and the second selecting chalcogenide material.

19. An array of memory cells, comprising:
a plurality of storage materials, wherein each of the plurality of storage materials is formed between a respective first selecting chalcogenide material and a respective second selecting chalcogenide material.

20. The array of claim 19, wherein each of the respective first selecting chalcogenide materials has a thickness that is equal to a thickness of each of the respective second selecting chalcogenide materials.

21. The array of claim 19, wherein each of the respective first selecting chalcogenide materials has a thickness that is greater than a thickness of each of the respective second selecting chalcogenide materials.

22. The array of claim 19, wherein each of the respective first selecting chalcogenide materials has a thickness that is less than a thickness of each of the respective second selecting chalcogenide materials.

23. The array of claim 19, wherein a first portion of the plurality of storage materials form a first tier of the array and a second portion of the plurality of storage materials form a second tier of the array.

24. The array of claim 23, wherein each of the memory cells is symmetric about a respective storage material.

25. The array of claim 19, wherein each of the plurality of storage materials comprises a respective storage chalcogenide material.

26. A method of forming a memory cell, the method comprising:
forming a first selecting chalcogenide material;
forming a storage material; and
forming a second selecting chalcogenide material, wherein the storage material is formed between the first selecting chalcogenide material the second selecting chalcogenide material.

27. The method of claim 26, wherein the first selecting chalcogenide material has a thickness that is equal to a thickness of the second selecting chalcogenide materials.

28. The method of claim 26, wherein the first selecting chalcogenide material has a thickness that is greater than a thickness of the second selecting chalcogenide materials.

29. The method of claim 26, wherein the first selecting chalcogenide material has a thickness that is less than a thickness of the second selecting chalcogenide materials.

30. The method of claim 26, wherein forming the storage material comprises forming a storage chalcogenide material.

31. A method of forming a memory cell, the method comprising:
forming a first selecting chalcogenide material on a first electrode material;
forming a second electrode material on the first selecting chalcogenide material;
forming a storage material on the second electrode material;
forming a third electrode material on the storage material;
forming a second selecting chalcogenide material on the third electrode material; and
forming a fourth electrode material on the second selecting chalcogenide material.

32. The method of claim 31, wherein the first selecting chalcogenide material has a first thickness and the second selecting chalcogenide material has a second thickness.

33. The method of claim 32, wherein the first thickness is equal to the second thickness.

34. The method of claim 32, wherein the first thickness is greater than the second thickness.

35. The method of claim 32, wherein the first thickness is less than the second thickness.

36. The method of claim 31, wherein forming a storage material comprises forming a storage chalcogenide material.
